(19) United States
(12) Patent Application Publication
(10) Pub. No.: US 2021/0295914 A1
(43) Pub. Date: Sep. 23, 2021

(54) STORAGE CONTROL DEVICE, STORAGE DEVICE, AND STORAGE CONTROL METHOD

(71) Applicant: SONY SEMICONDUCTOR SOLUTIONS CORPORATION, KANAGAWA (JP)

(72) Inventors: KEN ISHII, KANAGAWA (JP); KENICHI NAKANISHI, KANAGAWA (JP); HIDEAKI OKUBO, KANAGAWA (JP); YOSHIYUKI SHIBAHARA, KANAGAWA (JP); HARUHIKO TERADA, KANAGAWA (JP)

(21) Appl. No.: 17/250,494

(22) PCT Filed: Apr. 18, 2019
(86) PCT No.: PCT/JP2019/016624

§ 371 Date: Jan. 28, 2021

(30) Foreign Application Priority Data
Aug. 6, 2018 (JP) 2018-147899

(51) Int. Cl. G11C 13/00

(52) U.S. Cl. CPC G11C 13/0033; G11C 13/0061; G11C 13/0069; G11C 13/004

(57) ABSTRACT

A selector malfunction caused by a drift is prevented in a memory having a cross-point structure. A memory cell array is provided with a data area and a drift reference cell. An accumulated drift amount acquisition unit acquires an accumulated drift amount of the drift reference cell. A total drift amount reading unit reads a total drift amount stored in the data area. A refresh control unit adds the accumulated drift amount to the total drift amount to update the total drift amount as a new total drift amount. Further, the refresh control unit refreshes the data area of the memory cell array in a case where the new total drift amount exceeds a predetermined threshold value.

### TECHNICAL FIELD

The present technology relates to a storage control device. To be more specific, the present technology relates to a storage control device and a storage device that control memory refresh, and a processing method in these.

### BACKGROUND ART

In a resistance change type memory having a cross-point structure, each memory cell includes a variable resistance unit and a selector. In such a configuration, in a case where the selector has not been snapped for a long time (that is, has not been turned on), there is a fear that drift may occur. The effect of this drift increases the voltage required for the selector to snap. When the variable resistance unit of the memory cell is in a low resistance state and drift has occurred, the selector does not snap even when a reading voltage is applied, and no current flows through the cell of the cross-point memory. As a result, the resistance state of the variable resistance unit is erroneously determined. In order to recover the state of the memory cell in which such a data error is detected, a technique for refreshing the memory cell in which the data error is detected has been proposed (see, for example, PTL 1).

### CITATION LIST

### Patent Literature

### [PTL 1]

JP 2016-225007A

### SUMMARY

### Technical Problem

In the above-mentioned conventional technique, control is taken so that, when the number of read-ahead bit errors is equal to or more than a threshold value, strong refresh is performed, and when the number of read-ahead bit errors is equal to or less than the threshold value, weak refresh is performed. However, in this conventional technique, only the bit error that has occurred is focused on, and drift is not considered. Therefore, it is not possible to deal with a case where the drift progresses before the error appears clearly. For example, in a case where the memory cell is in a high resistance state, the resistance state of the variable resistance unit is not erroneously determined because no current flows through the memory even if a reading voltage is applied, regardless of the drift occurrence state of the selector. On the other hand, since the voltage required for snapping the selector rises due to the drift, there is a risk that the threshold value of the high resistance state becomes too high, and the setting becomes impossible.

The present technology has been created in view of such a situation, and an object is to prevent malfunction due to drift of the selector from occurring in a memory having a cross-point structure.

### Solution to Problem

The present technology is made to solve the above-mentioned problems, and the first aspect thereof is a storage control device and a storage device including an accumulated drift amount acquisition unit that acquires an accumulated drift amount of a drift reference cell of a memory cell array, a total drift amount reading unit that reads a total drift amount stored in a data area of the memory cell array, and a refresh control unit that adds the accumulated drift amount to the total drift amount to update the total drift amount as a new total drift amount and refreshes the data area in a case where the new total drift amount exceeds a predetermined threshold value, and a storage control method. This brings about the effect of updating the total drift amount according to the accumulated drift amount of the drift reference cell of the memory cell array so as to control the refresh of the data area on the basis of the total drift amount.

Further, in the first aspect, the accumulated drift amount acquisition unit may search for a drift amount while changing a reading threshold value for the drift reference cell. This brings about the effect of acquiring a reading threshold value corresponding to the amount of drift accumulated in the drift reference cell.

Further, in the first aspect, the memory cell array may include a resistance change type memory. The accumulated drift amount acquisition unit acquires a voltage of a threshold value when a resistance distribution read while the threshold value of a reading voltage for the drift reference cell is being changed reaches a predetermined state and converts the voltage of the threshold value into the accumulated drift amount. This brings about the effect of acquiring the voltage of the reading threshold value corresponding to the drift amount accumulated in the drift reference cell so as to convert the voltage into the accumulated drift amount. Note that the memory cell array may be a non-volatile memory.

Further, in the first aspect, a resistance state of the drift reference cell may include a low resistance state. The accumulated drift amount acquisition unit may acquire a voltage of the threshold value when approximately half of values in the read resistance distribution indicate a low resistance state. This brings about the effect of acquiring the voltage of the reading threshold value corresponding to the drift amount accumulated in the drift reference cell by using the resistance distribution so as to convert the voltage into the accumulated drift amount.

Further, in the first aspect, the storage control device may further include a total drift amount writing unit that writes a zero value as the total drift amount stored in the data area of the memory cell array when the refresh is performed and writes the new total drift amount as the total drift amount stored in the data area of the memory cell array in a case where the refresh is not performed. This brings about the effect of keeping the total drift amount stored in the data area of the memory cell array up to date.

Moreover, in the first aspect, the refresh control unit may determine whether or not the refresh is necessary when a power-on operation occurs. This brings about the effect of acquiring the drift amount accumulated during the power-off period to perform refresh as needed.

Still further, in the first aspect, the storage control device may include a timer that starts measuring time from the power-on operation. The refresh control unit may refresh the data area of the memory cell array when the timer reaches a predetermined value. This brings about the effect of controlling the refresh according to the time elapsed from the power-on.

Furthermore, in the first aspect, the accumulated drift amount acquisition unit may convert a value of the timer into the accumulated drift amount when a power-off operation occurs. The refresh control unit may add the accumulated drift amount to the total drift amount and update the total drift amount as a new total drift amount. This brings about the effect of acquiring the drift amount accumulated during normal operation and controlling the refresh.

### Advantageous Effect of Invention

The present technology can bring about an excellent effect of preventing malfunction due to drift of the selector from occurring in a memory having a cross-point structure. Note that the effects are not necessarily limited to those described herein, and may be any of the effects described in the present disclosure.

### BRIEF DESCRIPTION OF DRAWINGS

FIG. 1 is a diagram illustrating a configuration example of an information processing system according to an embodiment of the present technology.

FIG. 2 is a diagram illustrating a configuration example of a memory 300 according to an embodiment of the present technology.

FIG. 3 is a diagram illustrating a configuration example of a memory cell array 310 according to an embodiment of the present technology.

FIG. 4 is a diagram illustrating a three-dimensional image example of the memory cell array 310 according to an embodiment of the present technology.

FIG. 5 is a diagram illustrating the resistance state of a memory cell 311 according to an embodiment of the present technology.

FIG. 6 is a diagram illustrating a configuration example of a memory controller 200 according to an embodiment of the present technology.

FIG. 7 is a diagram illustrating an example of measurement of the drift amount of a drift reference cell 319 according to an embodiment of the present technology.

FIG. 8 is a diagram illustrating an example of drift amount conversion by a drift amount conversion unit 270 according to an embodiment of the present technology.

FIG. 9 is a flow chart illustrating an example of a processing procedure of the memory controller 200 according to a first embodiment of the present technology.

FIG. 10 is a flow chart illustrating an example of a processing procedure for a power-on process in an embodiment of the present technology.

FIG. 11 is a flow chart illustrating an example of a processing procedure for a reading request process of a drift reference cell of the memory 300 according to an embodiment of the present technology.

FIG. 12 is a flow chart illustrating an example of a processing procedure for the reading request process of the total drift amount of the memory 300 according to an embodiment of the present technology.

FIG. 13 is a flow chart illustrating an example of a processing procedure for a refresh request process of the memory 300 according to an embodiment of the present technology.

FIG. 14 is a flow chart illustrating an example of a processing procedure for a set process of the memory 300 according to an embodiment of the present technology.

FIG. 15 is a flow chart illustrating an example of a processing procedure for a reset process of the memory 300 according to an embodiment of the present technology.

FIG. 16 is a diagram illustrating a specific example of the refresh request process according to an embodiment of the present technology.

FIG. 17 is a diagram illustrating a configuration example of the memory controller 200 according to a second embodiment of the present technology.

FIG. 18 is a flow chart illustrating an example of a processing procedure of the memory controller 200 according to the second embodiment of the present technology.

FIG. 19 is a flow chart illustrating an example of a processing procedure of a normal operation process according to the second embodiment of the present technology.

FIG. 20 is a flow chart illustrating an example of a processing procedure for a power-off process according to an embodiment of the present technology.

FIG. 21 is a diagram illustrating a configuration example of the memory 300 according to a third embodiment of the present technology.

### DESCRIPTION OF EMBODIMENTS

Hereinafter, modes for carrying out the present technology (hereinafter referred to as embodiments) will be described. The description will be given in the following order.

1. First embodiment (example of performing refresh control when the power is turned on)

2. Second embodiment (example of performing refresh control even during normal operation after the power is turned on)

3. Third embodiment (example of performing refresh control in a memory)

### 1. First Embodiment

### [Configuration of Information Processing System]

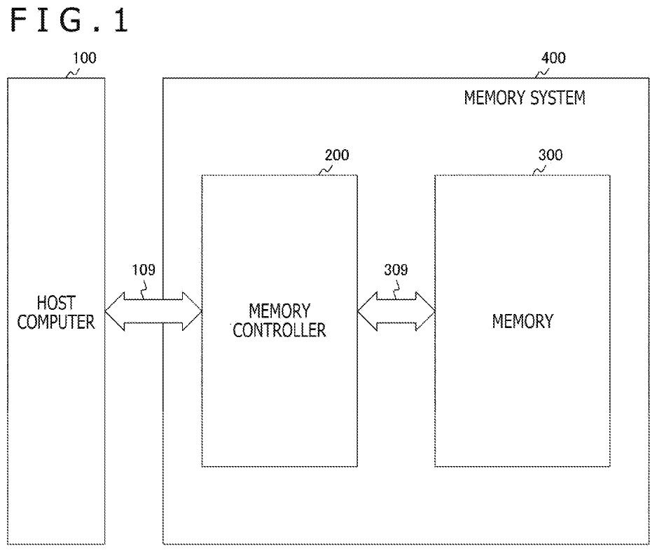

FIG. 1 is a diagram illustrating a configuration example of an information processing system according to an embodiment of the present technology. This information processing system includes a host computer 100, a memory controller 200, and a memory 300. The memory controller 200 and the memory 300 constitute a memory system 400.

The host computer 100 issues commands to instruct the memory 300 to perform reading processing and writing processing of data and the like. The host computer 100 includes a processor that executes processing of the host computer 100, and a controller interface for exchanging information with the memory controller 200. The host computer 100 and the memory controller 200 are connected by a signal line 109.

The memory controller 200 controls a request to the memory 300 according to a command from the host computer 100. The memory controller 200 and the memory 300 are connected by a signal line 309.

The memory 300 includes an access control unit and a memory cell array, as will be described later. The access control unit of the memory 300 accesses the memory cell according to the request from the memory controller 200.

In a case where a writing command is received from the host computer 100, the memory controller 200 receives data from the host computer 100, issues a writing request to the memory 300, and then transmits the data received from the host computer 100 to the memory 300 for writing.

In a case where a reading command is received from the host computer 100, the memory controller 200 issues a reading request to the memory 300, reads data from the memory 300, and transfers the data read from the memory 300 to the host computer 100.

### [Memory Configuration]

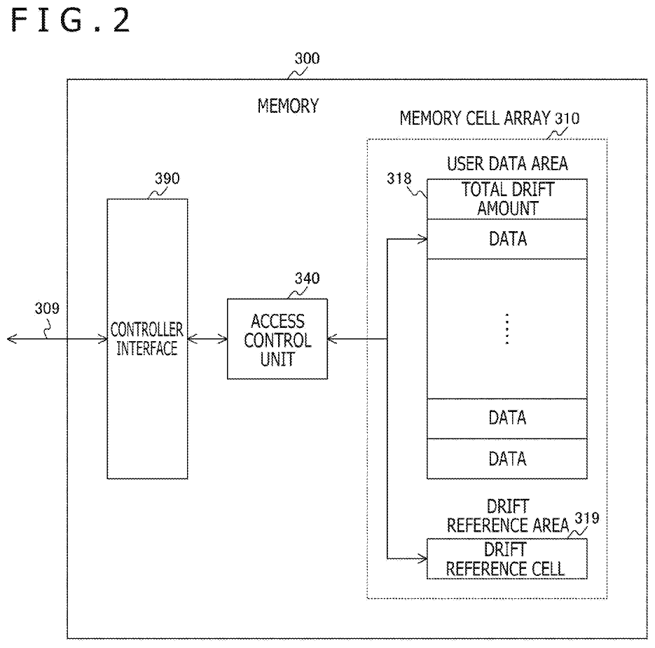

FIG. 2 is a diagram illustrating a configuration example of the memory 300 according to the embodiment of the present technology.

The memory 300 includes a memory cell array 310, an access control unit 340, and a controller interface 390.

The memory cell array 310 is formed by arranging a plurality of memory cells in an array shape (two-dimensional and a matrix shape). In the present embodiment, a non-volatile resistance change type memory is assumed as the memory cell.

The memory cell array 310 includes two areas, which are a user data area and a drift reference area. The user data area is an area for writing and reading user data as a normal memory area. The drift reference area is an area to be referred to for measuring the drift amount and includes drift reference cells 319.

The data stored in the user data area includes a total drift amount 318. The total drift amount 318 is the drift amount having been aggregated since the previous refresh has been performed in the user data area. Since the memory cell array 310 is assumed to be a non-volatile memory, though the power input (turning on) and cutting (turning off) are carried out intermittently, the drift is maintained during that period of time. Therefore, the total drift amount 318 indicates the total value from the time when the refresh is performed immediately before storing values regardless of whether the power is turned on or off. Note that the drift amount of the data in the user data area differs depending on the access frequency for each address, and the drift amount of the address that is not accessed at all has a maximum value. Therefore, the total drift amount 318 stores one total drift amount as the maximum value in the entire user data area, instead of storing a different value for each address.

The access control unit 340 controls reading and writing access to the memory cell array 310. The access control unit 340 has a function of controlling the word line and the bit line of the memory cell array 310. Incidentally, the access control unit 340 is an example of a total drift amount reading unit and a total drift amount writing unit described in the claims.

The controller interface 390 is an interface for communicating with the memory controller 200.

### [Memory Cell Array]

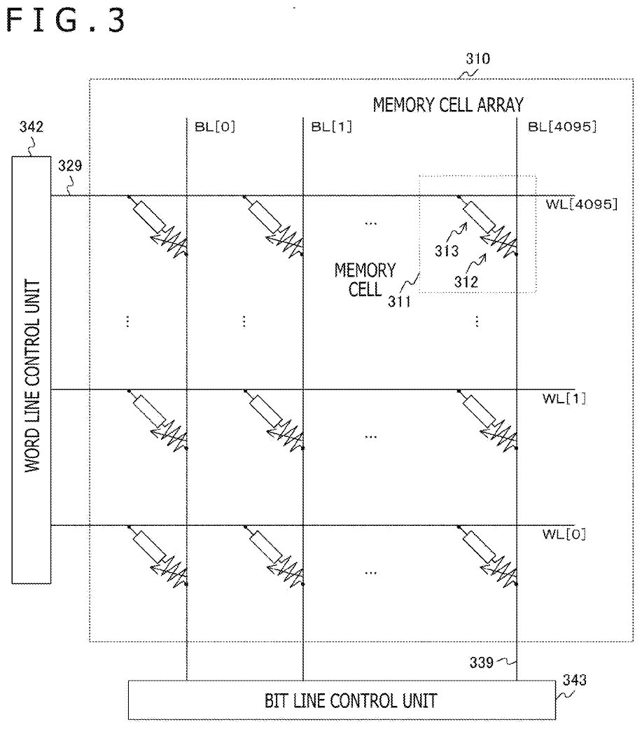

FIG. 3 is a diagram illustrating a configuration example of the memory cell array 310 according to the embodiment of the present technology.

The memory cell array 310 has a cross-point structure in which memory cells 311 are respectively connected between 4096 word lines 329 of WL [0] to WL [4095] and 4096 bit lines 339 of BL [0] to BL [4095], for example. The word lines 329 are controlled by a word line control unit 342, and the bit lines 339 are controlled by a bit line control unit 343. The word line control unit 342 and the bit line control unit 343 fulfill functions of the access control unit 340 described above.

The memory cell 311 is a resistance change type memory in which a variable resistor 312 and a selector 313 are connected in series. One end of the variable resistor 312 is connected to a bit line 339, and one end of the selector 313 is connected to a word line 329.

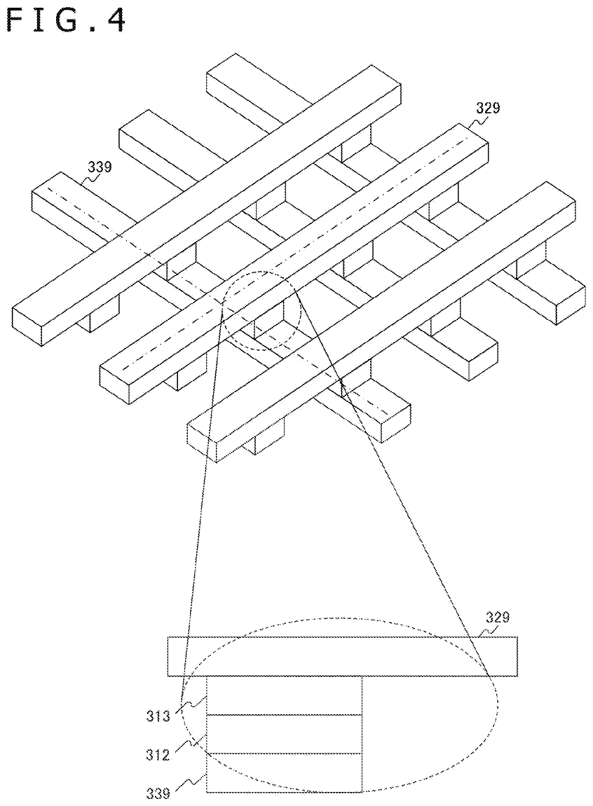

FIG. 4 is a diagram illustrating a three-dimensional image example of the memory cell array 310 according to the embodiment of the present technology.

As illustrated in FIG. 4, the memory cell 311 including the selector 313 and the variable resistor 312 is sandwiched between the word line 329 as the upper layer and the bit line 339 as the lower layer. As a result, the memory cell 311 can be arranged to be controlled at a position where the word line 329 and the bit line 339 intersect.

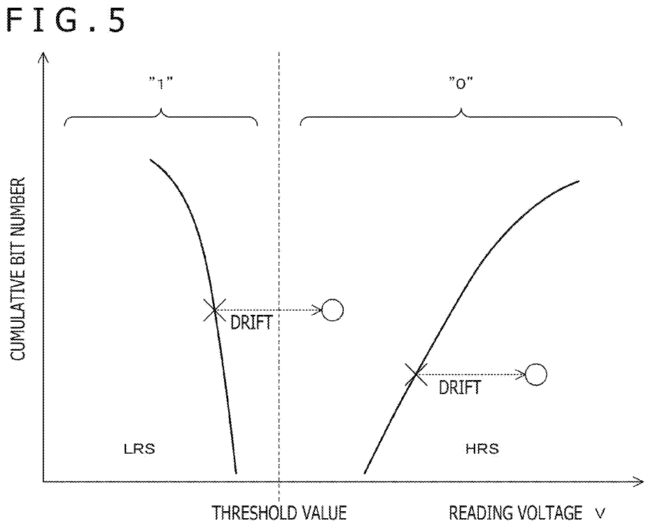

FIG. 5 is a diagram illustrating a resistance state of the memory cell 311 according to the embodiment of the present technology.

As described above, the memory cell 311 is assumed to be a resistance change type memory and indicates either a low resistance state (LRS) or a high resistance state (HRS). As illustrated in FIG. 5, the distribution of the cumulative number of bits when the reading voltage V is applied to the memory cell 311 is separated into either of the low resistance state or the high resistance state with a threshold value as the boundary.

In a case where the selector 313 is not snapped for a long time (that is, the selector is not turned on), there is a fear that drift may occur. Due to the effect of this drift, the voltage required for the selector 313 to snap rises in proportion to a logarithm (log) of time. When the variable resistor 312 of the memory cell 311 is in a low resistance state and drift has occurred, the selector 313 does not snap even when a reading voltage is applied, and no current flows through the memory cell 311. As a result, the resistance state of the variable resistor 312 that should be determined to be in the low resistance state is erroneously determined to be in the high resistance state. On the other hand, the memory cell 311 which is originally in the high resistance state keeps the high resistance state without change even if the drift has occurred, and no data error occurs.

### [Configuration of Memory Controller]

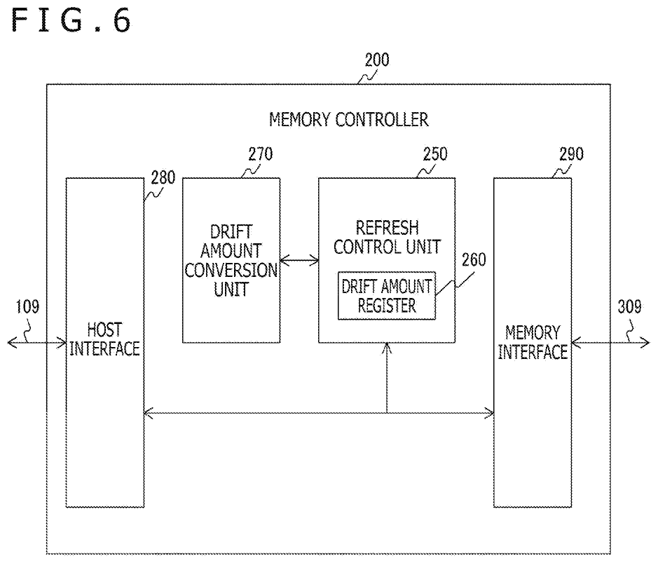

FIG. 6 is a diagram illustrating a configuration example of the memory controller 200 according to the embodiment of the present technology.

The memory controller 200 includes a refresh control unit 250, a drift amount register 260, a drift amount conversion unit 270, a host interface 280, and a memory interface 290.

The drift amount register 260 is a register that holds the drift amount of the user data area of the memory cell array 310.

The refresh control unit 250 controls refreshing operation of the memory cell array 310. When the power is turned on, the refresh control unit 250 reads the total drift amount 318 stored in the user data area of the memory cell array 310 and causes the drift amount register 260 to hold the total drift amount 318. However, the total drift amount 318 is the drift amount at the time when the power is turned off immediately before storing values. In order to obtain the latest drift amount, the memory controller 200 acquires the accumulated drift amount of the drift reference cell 319 of the memory cell array 310. Since this accumulated drift amount is obtained as a threshold value of the reading voltage as described later, it is necessary to convert the threshold value into a drift amount by the drift amount conversion unit 270.

The drift amount conversion unit 270 converts the threshold value of the reading voltage of the drift reference cell 319 of the memory cell array 310 into the drift amount. A specific example of a conversion process by the drift amount conversion unit 270 will be described later. Incidentally, the drift amount conversion unit 270 is an example of the accumulated drift amount acquisition unit described in the claims.

The host interface 280 is an interface for exchanging information with the host computer 100. The memory interface 290 is an interface for exchanging information with the memory 300. Note that the memory interface 290 is an example of a total drift amount reading unit and a total drift amount writing unit described in the claims.

It should be noted that the memory controller 200 may be provided with an error correction unit that calculates an error correction code (ECC) of the data recorded in the user data area of the memory 300 and executes an error correction processing of the data read from the user data area of the memory 300.

### [Measurement of Accumulated Drift Amount of Drift Reference Cell]

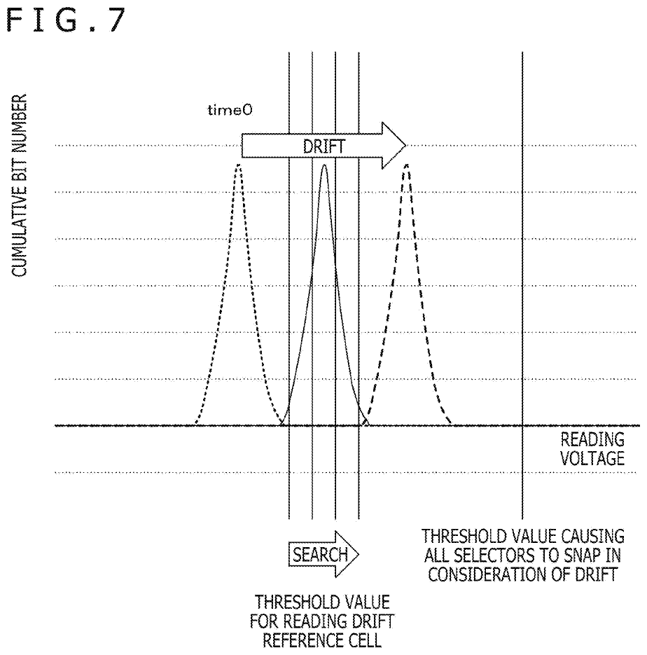

FIG. 7 is a diagram illustrating an example of measurement of the accumulated drift amount of the drift reference cell 319 according to the embodiment of the present technology.

As described above, when drift occurs, the distribution of the resistance state varies, and the threshold value of the reading voltage becomes a higher voltage. Here, assuming that the drift reference cell 319 of the memory cell array 310 is in a low resistance state, the value of the drift reference cell 319 is read while the reading threshold value is changed (shifted to a higher voltage). When the reading threshold value is low, the read value indicates “0” (high resistance state), but as this threshold value is raised, the read value changes to “1” (low resistance state). That is, the threshold value (voltage) when approximately half of the values indicate “1” as the distribution of the resistance state is searched for. However, since what is obtained here is the threshold value of the reading voltage, it is necessary to convert the value into a drift amount by the drift amount conversion unit 270.

At the time of reading the drift reference cell 319 of the memory cell array 310 to measure the accumulated drift amount, reading is performed at the end by using a threshold value causing the selectors 313 to reliably snap in order to finally initialize all the drift reference cells 319.

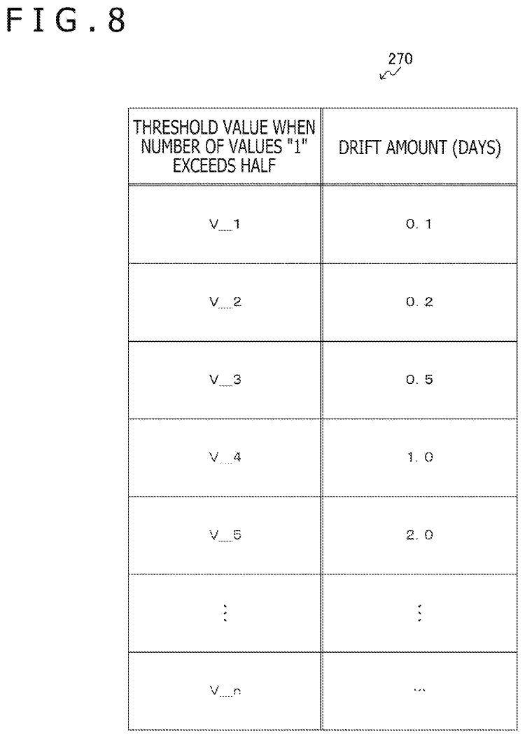

FIG. 8 is a diagram illustrating an example of drift amount conversion by the drift amount conversion unit 270 according to the embodiment of the present technology.

Here, it is assumed that the drift amount conversion unit 270 converts the threshold value (voltage) into the drift amount by table lookup. That is, the value of the drift reference cell 319 of the memory cell array 310 is read while the reading threshold value is shifted, and the corresponding drift amount is acquired by referring to the table on the basis of the threshold value (voltage) when half of the read values indicate “1.”

Although days are assumed as the unit of drift amount, time such as seconds, voltage value, or other normalized values may be used. Further, the correction may be performed according to the temperature and the number of selections.

Note that, in this example, the example of referring to the table has been described, but the amount may be calculated from the threshold value by performing calculation with use of a predetermined mathematical expression.

### [Operation]

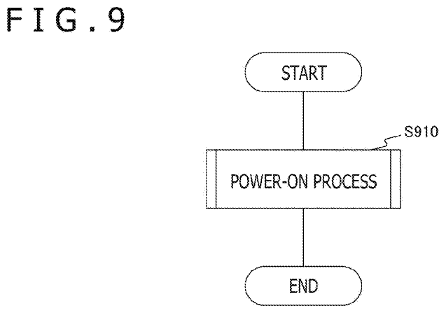

FIG. 9 is a flow chart illustrating an example of a processing procedure of the memory controller 200 according to the first embodiment of the present technology.

In the first embodiment, when the power is turned on, a process of acquiring the drift amount having been accumulated since the previous refresh is performed. That is, when the power-on operation occurs, the memory controller 200 executes a power-on process (step S910).

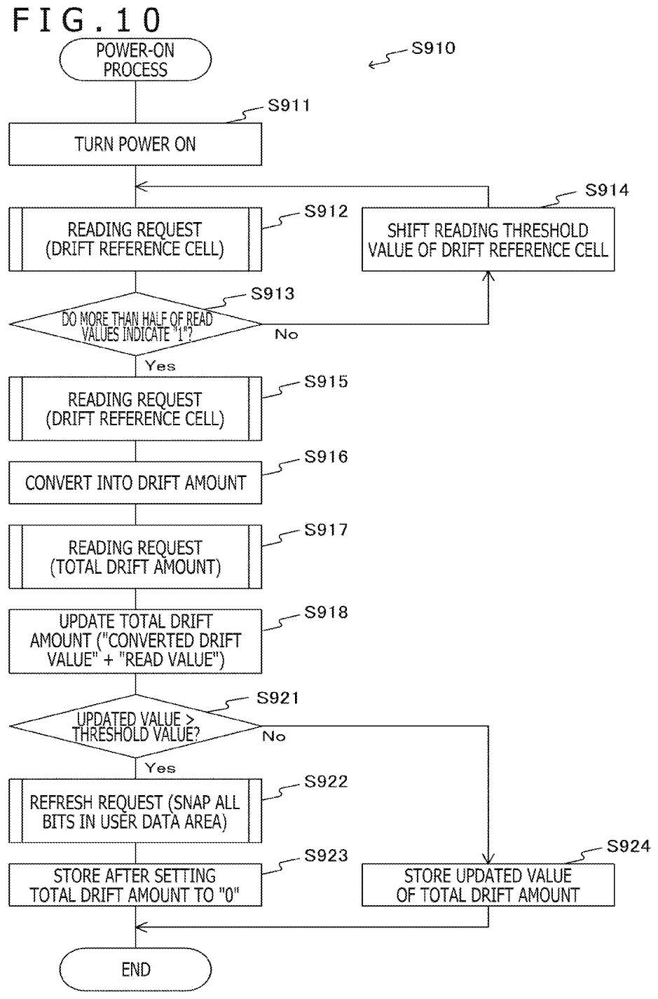

FIG. 10 is a flow chart illustrating an example of a processing procedure of the power-on process (step S910) according to the embodiment of the present technology.

When the power-on occurs (step S911), the memory controller 200 issues a reading request to read the drift reference cell 319 to the memory 300 via the memory interface 290 (step S912). In the memory 300, a reading threshold value different from that of a normal cell is used. That is, as described above, the voltage of the reading threshold value is started at a low voltage and shifted to a high voltage.

When half of the values read from the drift reference cell 319 in the memory 300 indicate “1” in the distribution (step S913: Yes), the reading threshold value at this time is considered to correspond to the accumulated drift amount. On the other hand, in a case where half of the values do not indicate “1” (step S913: No), the reading threshold value of the drift reference cell 319 is shifted (step S914), and the reading request to read the drift reference cell 319 is issued to the memory 300 again (step S912).

After half of the values indicate “1” (step S913: Yes), in order to finally initialize all the drift reference cells 319, a reading request to read the drift reference cell 319 is issued to the memory 300 at the end so that reading at a threshold value is performed to cause the selectors 313 to snap reliably (step S915).

The drift amount conversion unit 270 converts the reading threshold value of the drift reference cell 319 when half of the values indicate “1” into the drift amount, as described above (step S916).

Further, the memory controller 200 issues a reading request for the total drift amount 318 to the memory 300 via the memory interface 290 (step S917). Then, the refresh control unit 250 adds the value of the total drift amount 318 read from the memory 300 to the accumulated drift amount converted by the drift amount conversion unit 270 for updating as a new total drift amount (step S918).

In a case where the updated total drift amount exceeds a predetermined threshold value (step S921: Yes), the memory controller 200 issues a refresh request for the user data area to the memory 300 (step S922). As a result, all the bits of the user data area of the memory 300 are snapped, and the drift in the user data area is eliminated. Then, the memory controller 200 issues a writing request to the memory 300 via the memory interface 290 to set the total drift amount 318 to “0” (step S923).

On the other hand, in a case where the updated total drift amount does not exceed a predetermined threshold value (step S921: No), a writing request for writing the updated total drift amount into the total drift amount 318 is issued to the memory 300 via the memory interface 290 (step S924).

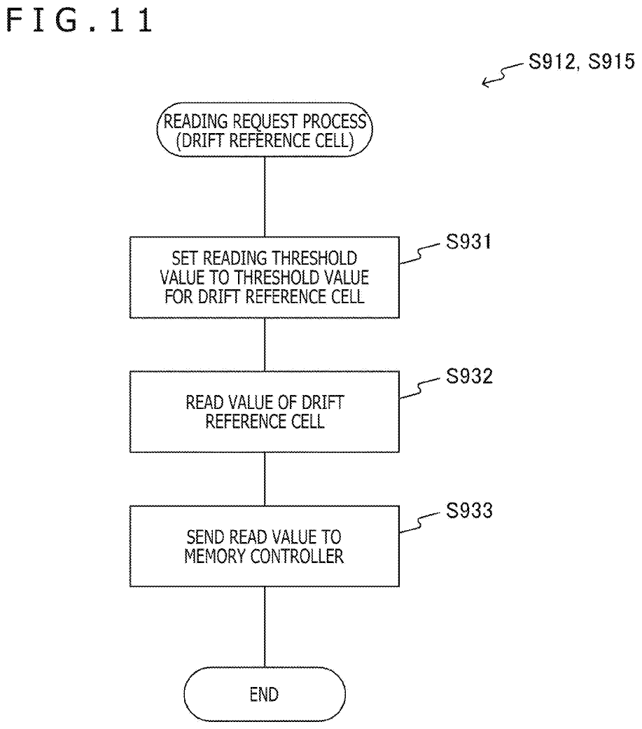

FIG. 11 is a flow chart illustrating an example of a processing procedure of a reading request process (steps S912 and S915) to read the drift reference cell of the memory 300 according to the embodiment of the present technology.

The access control unit 340 sets the reading threshold value to the threshold value for the drift reference cell 319 (step S931). Then, the access control unit 340 reads the value of the drift reference cell 319 from the memory cell array 310 (step S932) and supplies the read value to the memory controller 200 (step S933).

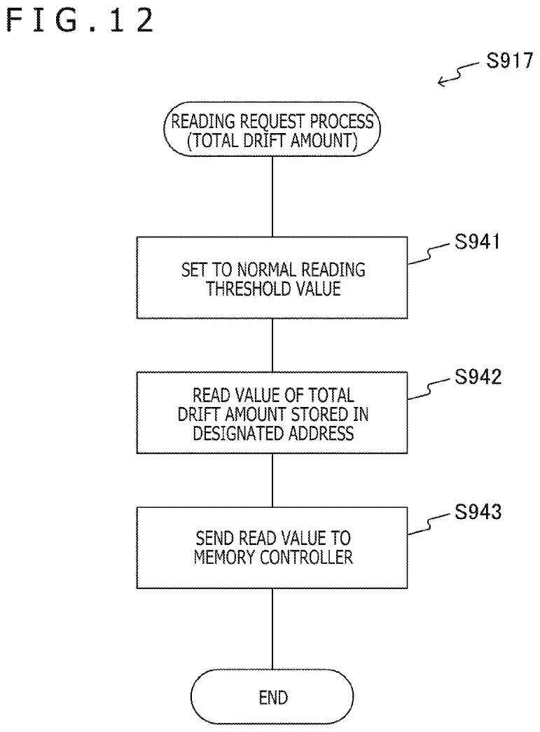

FIG. 12 is a flow chart illustrating an example of a processing procedure of the reading request process (step S917) of the total drift amount of the memory 300 according to the embodiment of the present technology.

The access control unit 340 sets the reading threshold value to a normal threshold value (step S941). Then, the access control unit 340 reads the value of the total drift amount 318 from the memory cell array 310 (step S942) and supplies the read value to the memory controller 200 (step S943).

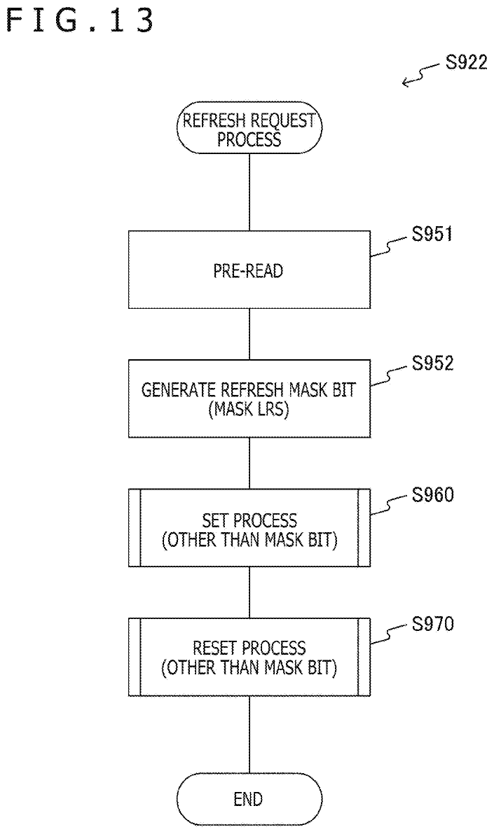

FIG. 13 is a flow chart illustrating an example of a processing procedure of a refresh request process (step S922) of the memory 300 according to the embodiment of the present technology.

The access control unit 340 executes pre-reading from the designated address of the memory cell array 310 (step S951). Then, a refresh mask bit is generated on the basis of the data subjected to pre-reading (step S952). At this time, “1” is set in the corresponding fresh mask bit so as to mask the bit indicating a low resistance state in the pre-read data. A set process (step S960) and a reset process (step S970) are performed using this fresh mask bit.

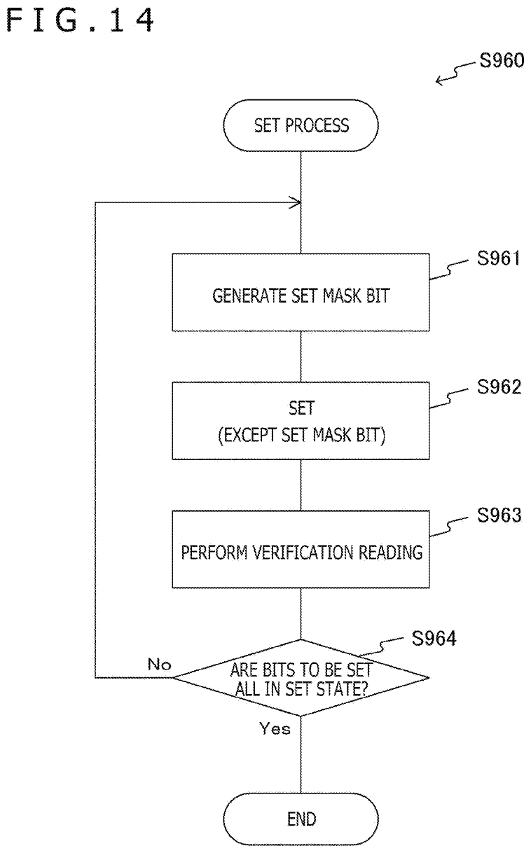

FIG. 14 is a flow chart illustrating an example of a processing procedure of the set process (step S960) of the memory 300 according to the embodiment of the present technology.

The access control unit 340 generates a set mask bit from the refresh mask bit (step S961). Then, “1” is set for the bit for which “1” is not set in the set mask bit (step S962).

The access control unit 340 performs verification reading to read the set data in order to verify (validate) the data (step S963). As a result, if all the bits to be set in the set mask bits are in the set state (step S964: Yes), the set process is considered to be successful and the process ends. On the other hand, if at least some of the bits to be set are not in the set state (step S964: No), it is assumed that the set process has failed, and the processes after step S961 are repeated.

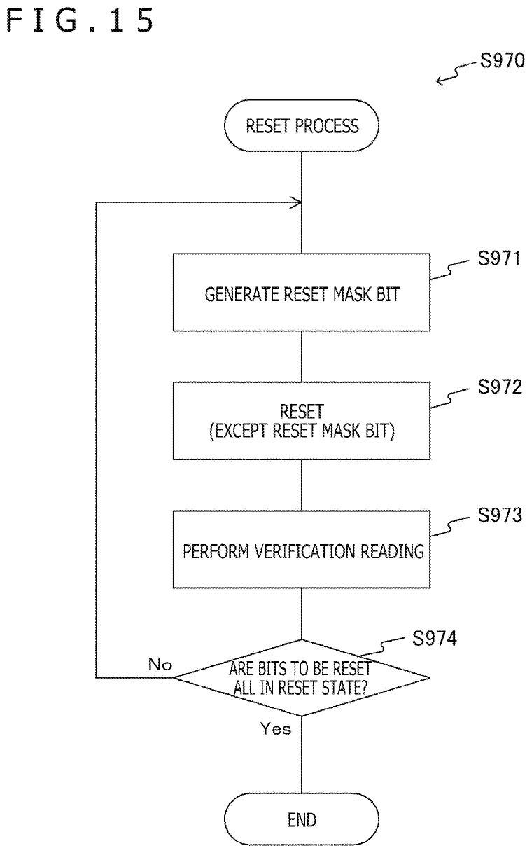

FIG. 15 is a flow chart illustrating an example of a processing procedure of the reset process (step S970) of the memory 300 according to the embodiment of the present technology.

Since this reset process is for carrying out reset in a manner similar to the set process described above, detailed description thereof is omitted.

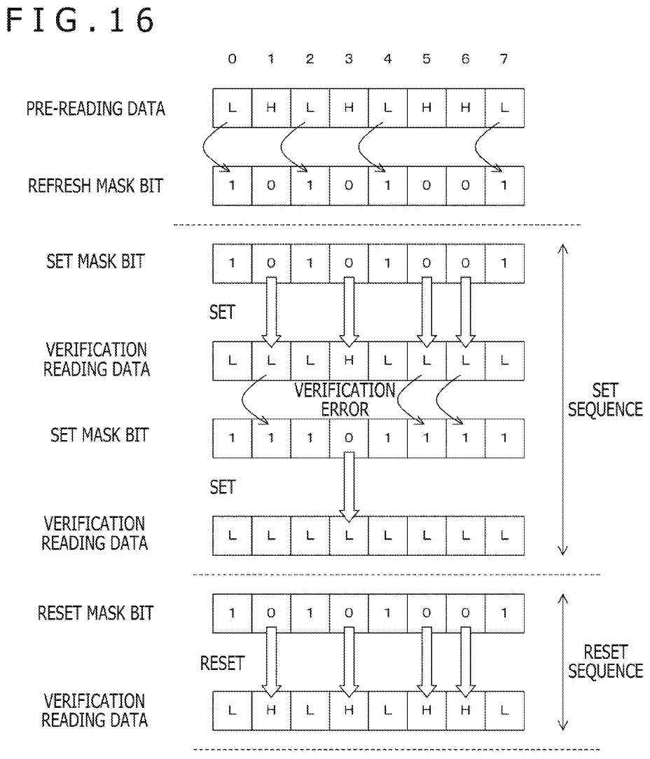

FIG. 16 is a diagram illustrating a specific example of the refresh request process according to the embodiment of the present technology. Incidentally, here, for the sake of simplicity, 8-bit width data is illustrated, but any data width may be used as the unit of refresh.

In this example, since the 0th, 2nd, 4th, and 7th bits of the pre-read data indicate a low resistance state, “1” is set for the corresponding bit of the refresh mask bits, and “0” is set for the other bits. Then, the same value is set in the set mask bit on the basis of the refresh mask bit, and “1” is set for the bit for which “1” is not set in the set mask bit.

After the set, verification reading is performed for verification, and the data is compared with the set mask bits. In this example, it is assumed that a verification error has occurred in the third bit. Therefore, the bits other than the third bit are set to “1,” and “1” is set again for the third bit for which “1” is not set in the set mask bit. As a result, if the verification is successful, the set sequence ends.

Next, the same value is set in the reset mask bit on the basis of the refresh mask bit, and the bit for which “1” is not set in the reset mask bit is reset to “0.” After performing the reset, verification reading is performed for verification, and the data is compared with the reset mask bits. As a result, if the verification is successful, the reset sequence ends.

As described above, according to the first embodiment of the present technology, the total drift amount 318 is updated by acquiring the drift amount having been accumulated since the previous refresh using the drift reference cell 319 so that the refresh of the user data area can be controlled.

### 2. Second Embodiment

In the above-mentioned first embodiment, the necessity of refresh is determined at the timing when the power-on operation occurs. On the other hand, in the second embodiment, the occurrence of drift due to the passage of time is monitored in the normal operation state after the power is turned on, and refresh is performed as necessary. Incidentally, since the overall configuration of the information processing system and the configuration of the memory 300 are similar to those of the first embodiment described above, detailed description thereof will be omitted.

### [Configuration of Memory Controller]

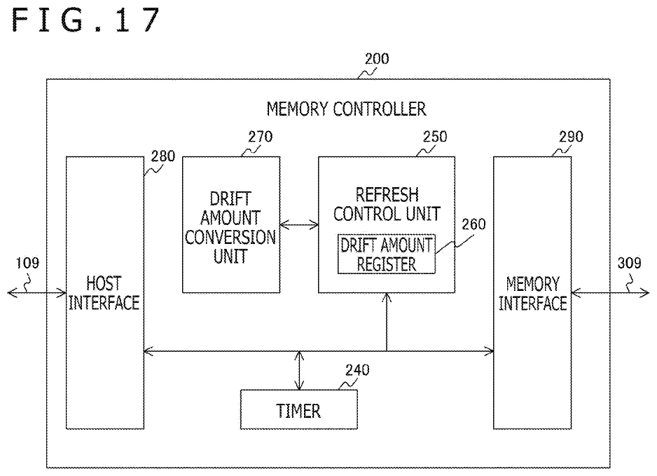

FIG. 17 is a diagram illustrating a configuration example of the memory controller 200 according to the second embodiment of the present technology.

The memory controller 200 according to the second embodiment includes a timer 240 in addition to the memory controller 200 according to the first embodiment described above. The timer 240 measures the elapsed time in the normal operation state and, when the count value exceeds the specified value, refresh is carried out.

### [Operation]

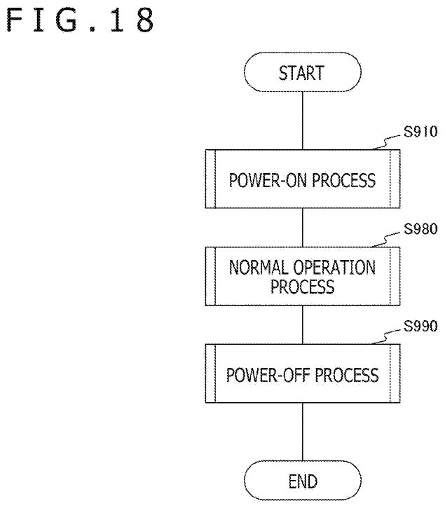

FIG. 18 is a flow chart illustrating an example of a processing procedure of the memory controller 200 according to the second embodiment of the present technology.

When the power-on operation occurs, the memory controller 200 executes the power-on process (step S910). The content of this power-on process is similar to that of the first embodiment described above.

Then, the memory controller 200 executes a normal operation process (step S980) using the timer 240 in the normal operation state after the power is turned on.

Further, when the power-off operation occurs, the memory controller 200 executes a power-off process (step S990).

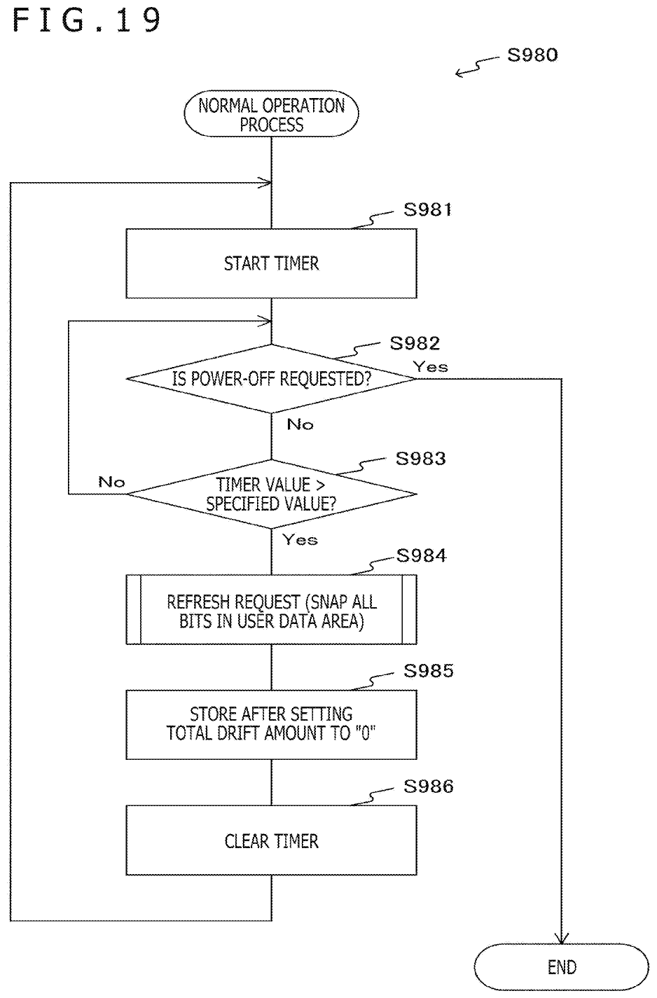

FIG. 19 is a flow chart illustrating an example of a processing procedure of the normal operation process (step S980) according to the second embodiment of the present technology.

After the power is turned on, the timer 240 starts time measurement (step S981). In a case where the count value of the timer 240 exceeds the specified value (step S983: Yes), the memory controller 200 issues a refresh request for the user data area to the memory 300 (step S984). As a result, all the bits of the user data area of the memory 300 are snapped, and the drift in the user data area is eliminated. Note that the content of this refresh request process is similar to the refresh request process in the above-mentioned power-on process.

Then, the memory controller 200 issues a writing request to set the total drift amount 318 to “0” to the memory 300 via the memory interface 290 (step S985). After that, the count value of the timer 240 is cleared to be “0” (step S986), and the timer 240 is started to measure time again (step S981).

If there is a request to turn off the power (step S982: Yes) before the count value of the timer 240 exceeds the specified value (step S983: No), the normal operation process ends.

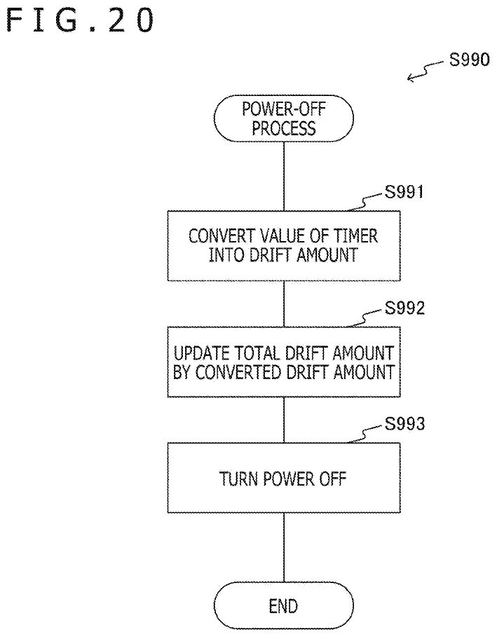

FIG. 20 is a flow chart illustrating an example of a processing procedure of the power-off process (step S990) according to the embodiment of the present technology.

When the power-off occurs, the drift amount conversion unit 270 converts the count value of the timer 240 into the drift amount to obtain the accumulated drift amount (step S991). Then, the refresh control unit 250 updates the total drift amount 318 by adding the converted drift amount to the total drift amount 318 (step S992). After that, the power proceeds to a turned-off state (step S993).

As described above, according to the second embodiment of the present technology, the elapsed time from the power-on is measured by the timer 240 and converted into a drift amount so that refresh can be performed as necessary in the normal operation state after the power is turned on.

### 3. Third Embodiment

In the above-described embodiment, an example of performing refresh control in the memory controller 200 has been described, but in the third embodiment, the refresh control is performed in the memory 300. Note that, since the overall configuration of the information processing system is similar to that of the first embodiment described above, detailed description thereof will be omitted.

### [Memory Configuration]

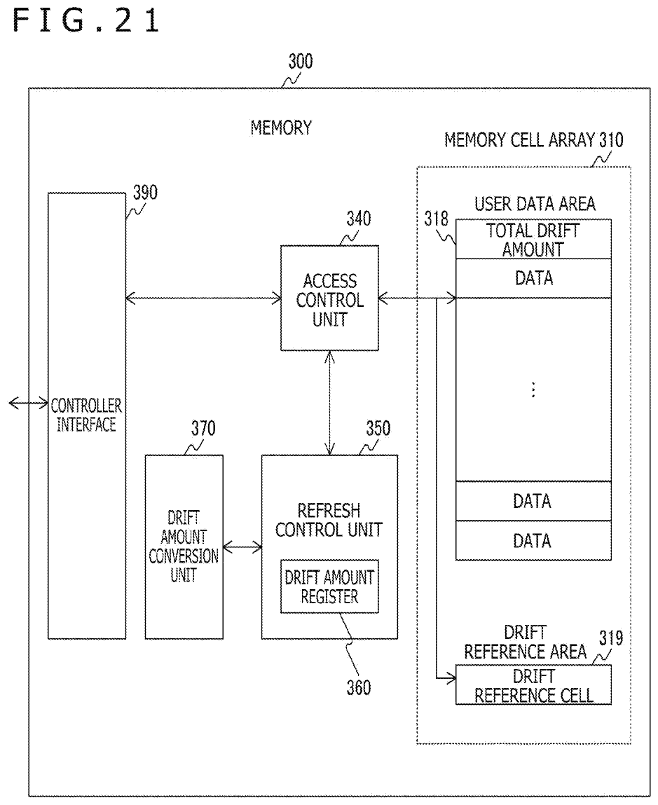

FIG. 21 is a diagram illustrating a configuration example of the memory 300 according to the third embodiment of the present technology.

The memory 300 according to the third embodiment includes a refresh control unit 350, a drift amount register 360, and a drift amount conversion unit 370, in addition to the memory cell array 310, the access control unit 340, and the controller interface 390. The refresh control unit 350, the drift amount register 360, and the drift amount conversion unit 370 have functions similar to those of the refresh control unit 250, the drift amount register 260, and the drift amount conversion unit 270 of the memory controller 200 according to the above-described first embodiment. As a result, in the third embodiment, the refresh control can be performed in the memory 300.

It should be noted that the above-described embodiments illustrate examples for embodying the present technology, and the matters in the embodiments and the matters specifying the invention in the claims have a correspondence relation with each other. Similarly, the matters specifying the invention within the scope of claims and the matters in the embodiments of the present technology having the same name have a correspondence relation with each other. However, the present technology is not limited to the embodiments, and can be embodied by applying various modifications to the embodiments without departing from the gist thereof.

Further, the processing procedures described in the above-described embodiments may be regarded as a method having a series of these procedures, or regarded as a program for causing a computer to execute a series of these procedures, or may further be regarded as a recording medium for storing the program. As the recording medium, for example, a CD (Compact Disc), an MD (MiniDisc), a DVD (Digital Versatile Disc), a memory card, a Blu-ray (registered trademark) Disc, and the like can be used.

It should be noted that the effects described in the present specification are merely examples and effects are not limited thereto, and other effects may be obtained.

The present technology can also have the following configurations.

(1)

A storage control device including:

an accumulated drift amount acquisition unit that acquires an accumulated drift amount of a drift reference cell of a memory cell array;

a total drift amount reading unit that reads a total drift amount stored in a data area of the memory cell array; and

a refresh control unit that adds the accumulated drift amount to the total drift amount to update the total drift amount as a new total drift amount and refreshes the data area in a case where the new total drift amount exceeds a predetermined threshold value.

(2)

The storage control device described in the above item (1), in which the accumulated drift amount acquisition unit searches for a drift amount while changing a reading threshold value for the drift reference cell.

(3)

The storage control device described in the above item (1) or (2), in which

the memory cell array includes a resistance change type memory, and

the accumulated drift amount acquisition unit acquires a voltage of a threshold value when a resistance distribution read while the threshold value of a reading voltage for the drift reference cell is being changed reaches a predetermined state and converts the voltage of the threshold value into the accumulated drift amount.

(4)

The storage control device described in the above item (3), in which

a resistance state of the drift reference cell includes a low resistance state, and

the accumulated drift amount acquisition unit acquires a voltage of the threshold value when approximately half of values in the read resistance distribution indicate a low resistance state.

(5)

The storage control device described in any one of the above items (1) to (4) further including:

a total drift amount writing unit that writes a zero value as the total drift amount stored in the data area of the memory cell array, when the refresh is performed, and writes the new total drift amount as the total drift amount stored in the data area of the memory cell array, in a case where the refresh is not performed.

(6)

The storage control device described in any one of the above items (1) to (5), in which the refresh control unit determines whether or not the refresh is necessary when a power-on operation occurs.

(7)

The storage control device described in the above item (6) further including:

a timer that starts measuring time from the power-on operation, in which

the refresh control unit refreshes the data area of the memory cell array when the timer reaches a predetermined value.

(8)

The storage control device described in the above item (7), in which

the accumulated drift amount acquisition unit converts a value of the timer into the accumulated drift amount when a power-off operation occurs, and

the refresh control unit adds the accumulated drift amount to the total drift amount and updates the total drift amount as a new total drift amount.

(9)

A storage device including:

a memory cell array including a data area and a drift reference cell;

an accumulated drift amount acquisition unit that acquires an accumulated drift amount of the drift reference cell;

a total drift amount reading unit that reads a total drift amount stored in the data area; and

a refresh control unit that adds the accumulated drift amount to the total drift amount to update the total drift amount as a new total drift amount and refreshes the data area in a case where the new total drift amount exceeds a predetermined threshold value.

(10)

The storage device described in the above item (9), in which the memory cell array includes a resistance change type memory.

(11)

The storage device described in the above item (9) or (10), in which the memory cell array includes a non-volatile memory.

(12)

A storage control method including:

a procedure of acquiring an accumulated drift amount of a drift reference cell of a memory cell array;

a procedure of reading a total drift amount stored in a data area of the memory cell array; and

a procedure of adding the accumulated drift amount to the total drift amount to update the total drift amount as a new total drift amount and refreshing the data area in a case where the new total drift amount exceeds a predetermined threshold value.

### REFERENCE SIGNS LIST

100 Host computer
200 Memory controller
240 Timer
250 Refresh control unit
260 Drift amount register
270 Drift amount conversion unit
280 Host interface
290 Memory interface
300 Memory
310 Memory cell array
311 Memory cell
312 Variable resistor
313 Selector
318 Total drift amount
319 Drift reference cell
329 Word line
339 Bit line
340 Access control unit
342 Word line control unit
343 Bit line control unit
350 Refresh control unit
360 Drift amount register
370 Drift amount conversion unit
390 Controller interface
400 Memory system

1. A storage control device comprising:
an accumulated drift amount acquisition unit that acquires an accumulated drift amount of a drift reference cell of a memory cell array;
a total drift amount reading unit that reads a total drift amount stored in a data area of the memory cell array; and
a refresh control unit that adds the accumulated drift amount to the total drift amount to update the total drift amount as a new total drift amount and refreshes the data area in a case where the new total drift amount exceeds a predetermined threshold value.

2. The storage control device according to claim 1, wherein the accumulated drift amount acquisition unit searches for a drift amount while changing a reading threshold value for the drift reference cell.

3. The storage control device according to claim 1, wherein
the memory cell array includes a resistance change type memory, and
the accumulated drift amount acquisition unit acquires a voltage of a threshold value when a resistance distribution read while the threshold value of a reading voltage for the drift reference cell is being changed reaches a predetermined state and converts the voltage of the threshold value into the accumulated drift amount.

4. The storage control device according to claim 3, wherein
a resistance state of the drift reference cell includes a low resistance state, and
the accumulated drift amount acquisition unit acquires a voltage of the threshold value when approximately half of values in the read resistance distribution indicate a low resistance state.

5. The storage control device according to claim 1 further comprising:
a total drift amount writing unit that writes a zero value as the total drift amount stored in the data area of the memory cell array, when the refresh is performed, and writes the new total drift amount as the total drift amount stored in the data area of the memory cell array, in a case where the refresh is not performed.

6. The storage control device according to claim 1, wherein the refresh control unit determines whether or not the refresh is necessary when a power-on operation occurs.

7. The storage control device according to claim 6 further comprising:
a timer that starts measuring time from the power-on operation, wherein
the refresh control unit refreshes the data area of the memory cell array when the timer reaches a predetermined value.

8. The storage control device according to claim 7, wherein
the accumulated drift amount acquisition unit converts a value of the timer into the accumulated drift amount when a power-off operation occurs, and
the refresh control unit adds the accumulated drift amount to the total drift amount and updates the total drift amount as a new total drift amount.

9. A storage device comprising:
a memory cell array including a data area and a drift reference cell;
an accumulated drift amount acquisition unit that acquires an accumulated drift amount of the drift reference cell;
a total drift amount reading unit that reads a total drift amount stored in the data area; and
a refresh control unit that adds the accumulated drift amount to the total drift amount to update the total drift amount as a new total drift amount and refreshes the data area in a case where the new total drift amount exceeds a predetermined threshold value.

10. The storage device according to claim 9, wherein the memory cell array includes a resistance change type memory.

11. The storage device according to claim 9, wherein the memory cell array includes a non-volatile memory.

12. A storage control method comprising:
a procedure of acquiring an accumulated drift amount of a drift reference cell of a memory cell array;
a procedure of reading a total drift amount stored in a data area of the memory cell array; and
a procedure of adding the accumulated drift amount to the total drift amount to update the total drift amount as a new total drift amount and refreshing the data area in a case where the new total drift amount exceeds a predetermined threshold value.
